(19) United States
(12) Patent Application Publication
(10) Pub. No.: US 2026/0353889 A1
(43) Pub. Date: Nov. 5, 2026

(54) DISPLAY PANEL, DISPLAY APPARATUS AND TILED DISPLAY APPARATUS

(71) Applicants: BOE MLED Technology Co., Ltd., Beijing (CN); BOE Technology Group Co., Ltd., Beijing (CN); Beijing BOE Technology Development Co., Ltd., Beijing (CN)

(72) Inventors: Mingming JIA, Beijing (CN); Jing WANG, Beijing (CN); Mengqing LIU, Beijing (CN); Huaimin WANG, Beijing (CN); Lili WANG, Beijing (CN); Sha FENG, Beijing (CN); Jingping ZHAO, Beijing (CN); Shanshan FENG, Beijing (CN); Chao LIU, Beijing (CN); Ming ZHAI, Beijing (CN); Qi QI, Beijing (CN)

(73) Assignees: BOE MLED Technology Co., Ltd., Beijing (CN); BOE Technology Group Co., Ltd., Beijing (CN); Beijing BOE Technology Development Co., Ltd., Beijing (CN)

(21) Appl. No.: 19/148,696

(22) PCT Filed: Jun. 12, 2024
(86) PCT No.: PCT/CN2024/098701

§ 371 Date: Jul. 17, 2025

(30) Foreign Application Priority Data
Jul. 4, 2023 (CN) 202310813867.8

(51) Int. Cl. H10H 29/49

(52) U.S. Cl. CPC H10H 29/49

(57) ABSTRACT

A display panel includes a substrate, a bridging structure, back electrodes, and connecting traces. The substrate includes first and second surfaces, and first side surfaces, at least one of which is a first selected side surface. The bridging structure, on the second surface, includes third and fourth surfaces. A portion of the bridging structure proximate to the first selected side surface is provided with notches each having an opening facing the first selected side surface. Each notch corresponds to one back electrode on the fourth surface.

Each connecting trace includes a first trace on the first surface, a second trace on the first selected side surface, and a third trace on the second surface. The third trace includes a second portion in the notch, a third portion on the fourth surface and connected to the back electrode, and a first portion between the second portion and the second trace.

### CROSS-REFERENCE TO RELATED APPLICATIONS

This application is a national phase entry under 35 USC 371 of International Patent Application No. PCT/CN 2024/098701 filed on Jun. 12, 2024, which claims priority to Chinese Patent Application No. 202310813867.8 filed on Jul. 4, 2023, each are incorporated herein by reference in their entirety.

### TECHNICAL FIELD

The present disclosure relates to the field of display technologies, and in particular, to a display panel, a display apparatus and a tiled display apparatus.

### BACKGROUND

The use of micro light-emitting diodes (Micro LEDs) or sub-millimeter light-emitting diodes (mini light-emitting diodes, Mini LEDs) as pixels in display panels has received extensive attention and research. At present, it is difficult to manufacture a large-sized display apparatus at one time due to the difficulty of the mass transfer yield, so a large-sized tiled display apparatus is proposed which is usually formed and assembled by using a method of tiling a plurality of small-sized display apparatuses.

At present, in order to reduce frame sizes of display apparatuses to reduce the width of a tiling seam of a tiled display apparatus, for a single display panel, traces disposed on a side surface of the display panel may be used to fulfill a connection between traces on a display surface and a driver (e.g., a circuit board or a driving chip) disposed on a non-display surface. In this way, after a plurality of display panels are assembled to form a large-sized tiled display apparatus, adjacent display panels may have a relatively small spacing therebetween, thereby improving the display quality.

### SUMMARY

In an aspect, a display panel is provided. The display panel includes a substrate, a bridging structure, a plurality of back electrodes, and a plurality of connecting traces. The substrate includes a first surface and a second surface disposed opposite each other, and a plurality of first side surfaces connecting the first surface and the second surface, where at least one first side surface in the plurality of first side surfaces is a first selected side surface. The bridging structure is disposed on the second surface and includes a third surface and a fourth surface disposed opposite each other, the third surface being closer to the substrate relative to the fourth surface. A portion of the bridging structure stacked proximate to the first selected side surface is provided with a plurality of notches, and the plurality of notches each have an opening facing the first selected side surface. The plurality of back electrodes are arranged in parallel and at intervals on the fourth surface, and each notch in the plurality of notches is arranged in correspondence with one back electrode. The plurality of connecting traces are arranged in parallel and at intervals. Each connecting trace includes a first trace located on a side of the first surface, a second trace located on a side of the first selected side surface, and a third trace located on a side of the second surface; the third trace includes a first portion, a second portion and a third portion connected in sequence; and the second portion is located in the notch, the third portion is located on a side of the fourth surface and connected to the back electrode, and the first portion is located between the second portion and the second trace.

In some embodiments, a dimension of the second portion in a first direction is less than a dimension of each of the first portion and the third portion in the first direction, the first direction being perpendicular to an extension direction of the third trace.

In some embodiments, the second portion includes a first sub-portion and a second sub-portion, an average distance between the second sub-portion and the second surface is greater than an average distance between the first sub-portion and the second surface, the second sub-portion is connected to the third portion, and the first sub-portion is connected to the first portion. A dimension of the first sub-portion in a second direction is greater than a dimension of the second sub-portion in the second direction, the second direction being an extension direction of the third trace.

In some embodiments, a thickness of the first sub-portion is greater than or equal to a thickness of the first portion, and the thickness of the first sub-portion is greater than a thickness of the third portion.

In some embodiments, a thickness of a portion of the first portion proximate to the bridging structure is greater than a thickness of a portion of the first portion proximate to the first selected side surface.

In some embodiments, a dimension of the notch in a first direction is less than a dimension of the back electrode in the first direction, the first direction being perpendicular to an extension direction of the third trace.

In some embodiments, a ratio of the dimension of the notch in the first direction to the dimension of the back electrode in the first direction ranges from 0.5 to 0.6.

In some embodiments, the notch has a plurality of cross-sections perpendicular to the second surface and parallel to a first direction; and a dimension, in the first direction, of a cross-section farthest away from the first selected side surface in the plurality of cross-sections is less than or equal to a dimension, in the first direction, of a cross-section closest to the first selected side surface in the plurality of cross-sections, the first direction being perpendicular to an extension direction of the third trace.

In some embodiments, an orthographic projection of the notch on the second surface has a shape of a rectangle, trapezoid, semi-circle or semi-ellipse.

In some embodiments, the display panel further includes a buffer structure, disposed on a side wall of the notch proximate to the back electrode, and the second portion is located in the notch and a portion of the second portion is located on the buffer structure.

In some embodiments, a dimension, in a thickness direction of the substrate, of a portion of the buffer structure proximate to the back electrode is less than or equal to a dimension, in the thickness direction of the substrate, of the notch.

In some embodiments, the notch has a first spacing in a second direction with the back electrode, the second direction being an extension direction of the third trace; and a ratio of a dimension of the notch in the second direction to the first spacing ranges from 0.6 to 1.

In some embodiments, a side of the bridging structure proximate to the first selected side surface has a second spacing in a second direction with the first selected side surface, the second direction being an extension direction of the third trace.

In some embodiments, the notch extends from the fourth surface to the third surface.

In some embodiments, the notch passes through, from the fourth surface, a portion of the bridging structure.

In some embodiments, the notch has a bottom surface inclined toward the back electrode, at an obtuse angle formed with the second surface.

In some embodiments, the obtuse angle ranges from 120° to 150°.

In another aspect, a display apparatus is provided. The display apparatus includes the display panel as described in any of the above embodiments and a driving circuit board. The driving circuit board is electrically connected to the display panel and configured to drive the display panel to display an image.

In yet another aspect, a tiled display apparatus is provided. The tiled display apparatus includes a plurality of display apparatuses, each as described in any of the above embodiments, tiled together.

In still another aspect, a tiled display apparatus is provided. The tiled display apparatus includes a plurality of display panels, each as described in any of the above embodiments, tiled together.

### BRIEF DESCRIPTION OF THE DRAWINGS

In order to describe technical solutions in the present disclosure more clearly, the accompanying drawings to be used in some embodiments of the present disclosure will be introduced briefly. It is obvious that the accompanying drawings to be described below are merely drawings of some embodiments of the present disclosure, and a person of ordinary skill in the art can obtain other drawings in accordance with those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a cross-sectional view showing a structure of a display panel in accordance with some embodiments;

FIG. 2 is a plan view showing a structure of a display panel in accordance with some embodiments;

FIG. 3 is another cross-sectional view showing a structure of a display panel in accordance with some embodiments;

FIG. 4 is a top view showing a partial structure of a display panel in accordance with some embodiments;

FIG. 5 is a top view showing a partial structure of a display panel in accordance with some embodiments;

FIG. 6 is a top view showing a partial structure of a display panel in accordance with some embodiments;

FIG. 7 is another cross-sectional view showing a structure of a display panel in accordance with some embodiments;

FIG. 8A is another cross-sectional view showing a structure of a display panel in accordance with some embodiments;

FIG. 8B is a cross-sectional view showing a structure of a partial connecting trace in accordance with some embodiments;

FIG. 9 is another cross-sectional view showing a structure of a display panel in accordance with some embodiments;

FIG. 10A is a top view showing structures of notches of a display panel in accordance with some embodiments;

FIG. 10B is another top view showing structures of notches of a display panel in accordance with some embodiments;

FIG. 10C is another top view showing structures of notches of a display panel in accordance with some embodiments;

FIG. 10D is another top view showing structures of notches of a display panel in accordance with some embodiments;

FIG. 10E is another top view showing structures of notches of a display panel in accordance with some embodiments;

FIG. 10F is another top view showing structures of notches of a display panel in accordance with some embodiments;

FIG. 11A is a cross-sectional view showing a structure of a display panel in accordance with some embodiments;

FIG. 11B is another cross-sectional view showing a structure of a display panel in accordance with some embodiments;

FIG. 12 is a top view showing a partial structure of a display panel in accordance with some embodiments;

FIG. 13 is a cross-sectional view showing a structure of a display panel in accordance with some embodiments;

FIG. 14A is another cross-sectional view showing a structure of a display panel in accordance with some embodiments;

FIG. 14B is another cross-sectional view showing a structure of a display panel in accordance with some embodiments;

FIG. 15 is a plan view showing a structure of a display apparatus in accordance with some embodiments;

FIG. 16 is a plan view showing a structure of a display apparatus in accordance with some embodiments;

FIG. 17 is a plan view showing a structure of a tiled display apparatus in accordance with some embodiments;

FIG. 18 is a plan view showing a structure of a display apparatus in accordance with some embodiments;

FIG. 19 is a plan view showing a structure of a tiled display apparatus in accordance with some embodiments;

FIG. 20A is a structural diagram corresponding to a step of manufacturing a display panel in accordance with some embodiments;

FIG. 20B is a structural diagram corresponding to a step of manufacturing a display panel in accordance with some embodiments;

FIG. 20C is a structural diagram corresponding to a step of manufacturing a display panel in accordance with some embodiments;

FIG. 20D is a structural diagram corresponding to a step of manufacturing a display panel in accordance with some embodiments; and

FIG. 20E is a structural diagram corresponding to a step of manufacturing a display panel in accordance with some embodiments.

### DETAILED DESCRIPTION

The technical solutions in some embodiments of the present disclosure will be described clearly and completely below with reference to the accompanying drawings. It is obvious that the described embodiments are merely some but not all embodiments of the present disclosure. All other embodiments obtained by a person of ordinary skill in the art based on the embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of” and “multiple” both mean two or more unless otherwise specified.

Some embodiments may be described using the terms “coupled,” “connected” and their derivatives. The term “connected” should be understood in a broad sense. For example, the term “connected” may mean a fixed connection, a detachable connection, or an integrated connection; and the term “connected” may mean a direct connection or an indirect connection via an intermediate medium. The term “coupled” indicates that, for example, two or more than two components are in direct physical or electrical contact. The term “coupled” or “communicatively coupled” may also indicate that two or more than two components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation, or other action that is “based on” one or more of the stated conditions or values may, in practice, be based on additional conditions or values exceeding those stated.

As used herein, the term such as “about,” “substantially” or “approximately” includes a stated value and an average value within an acceptable range of deviation of a particular value, and the acceptable range of deviation is determined by a person of ordinary skill in the art in view of the measurement in question and errors associated with measurement of a particular quantity (i.e., the limitation of the measurement system).

The terms such as “parallel,” “perpendicular” and “equal” as used herein include a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, where an acceptable range of deviation of the approximate parallelism may be, for example, a deviation within 5°; the term “perpendicular” includes absolute perpendicularity and approximate perpendicularity, where an acceptable range of deviation of the approximate perpendicularity may also be, for example, a deviation within 5°; and the term “equal” includes absolute equality and approximate equality, and an acceptable range of deviation of the approximate equality may be a difference between two equals being less than or equal to 5% of either of the two equals.

It should be understood that, when a layer or element is referred to as being on another layer or substrate, it may mean that the layer or element is directly on the another layer or substrate, or it may mean that an intermediate layer exists between the layer or element and the another layer or substrate.

Exemplary embodiments are described herein with reference to sectional views and/or plan views that are schematic illustrations of idealized embodiments. In the accompanying drawings, thicknesses of layers and sizes of regions/areas are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

In order to improve the product reliability, as well as to reduce transportation and maintenance costs, a large-sized display apparatus may be assembled and formed by tiling a plurality of small-sized display apparatuses.

In order to avoid the sense of fragmentation of a display image caused by tiling, it is necessary to reduce a frame size of a single small-sized display apparatus to reduce the width of a tiling seam. The small-sized display apparatus includes a display panel. For example, it is possible to fulfill a connection between traces located on a side of a display surface of the display panel and a circuit board (e.g., a flexible circuit board) disposed on a side of a non-display surface of the display panel via side traces. In this way, after a plurality of small-sized display apparatuses are tiled together to form a large-sized display apparatus, adjacent small-sized display apparatuses may have a relatively small spacing therebetween, thereby enabling the width of a tiling seam of the large-sized display apparatus formed by tiling the plurality of small-sized display apparatuses to be reduced, allowing the display quality to be improved.

The display panel, the display apparatus, and the tiled display apparatus, which are provided by the present disclosure, will be described below in turn.

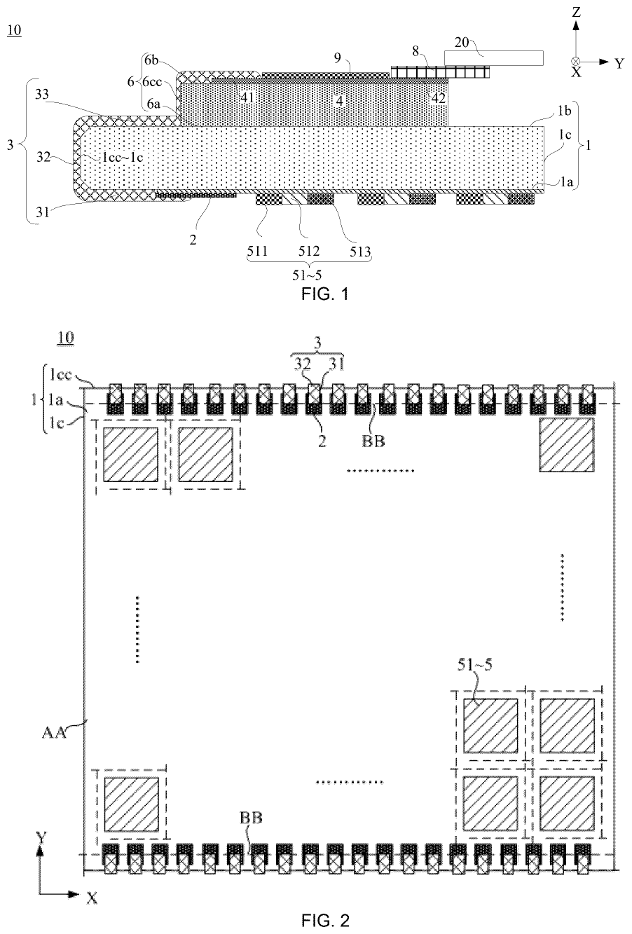

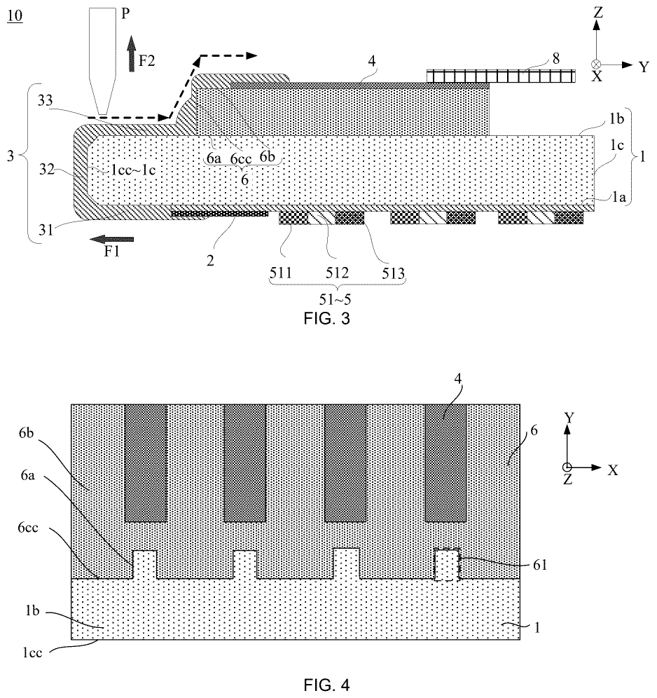

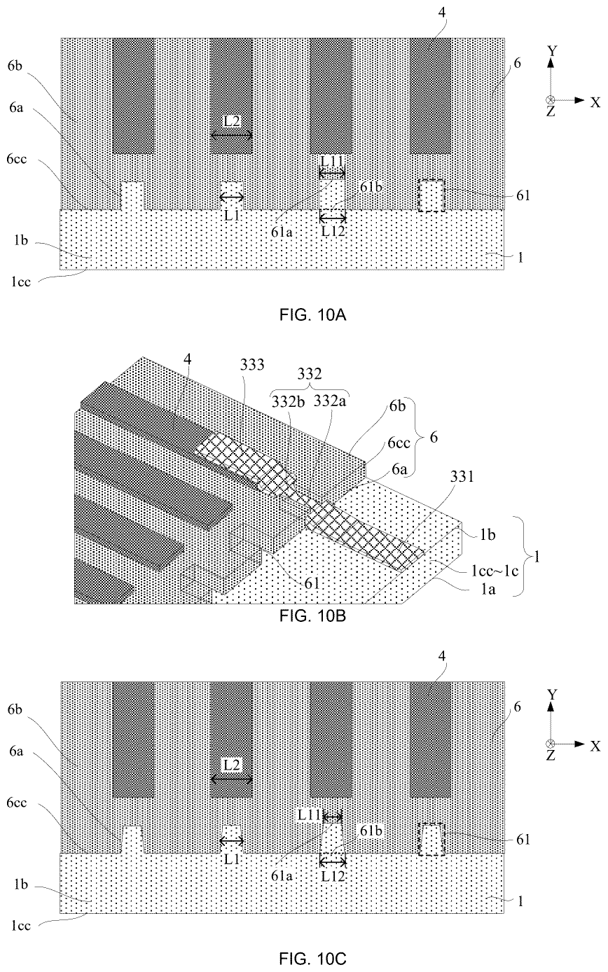

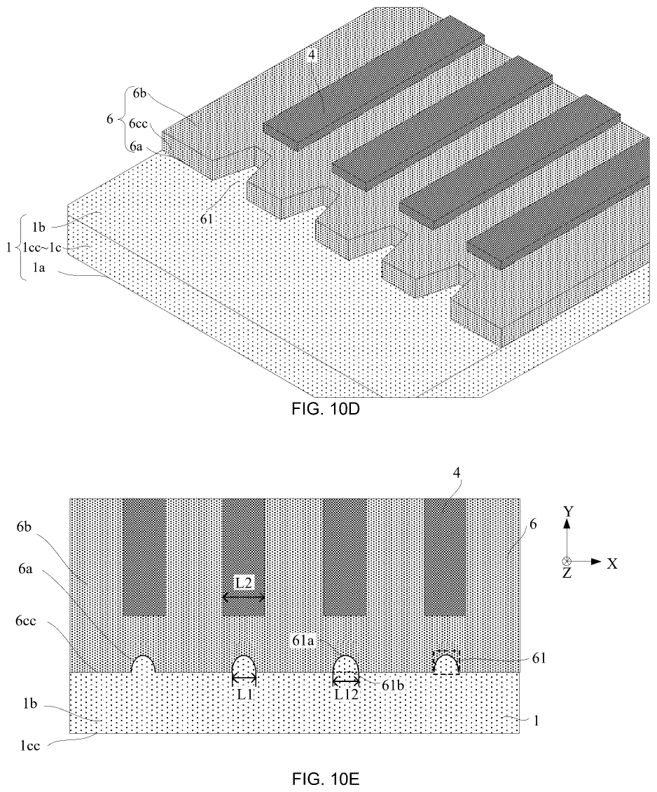

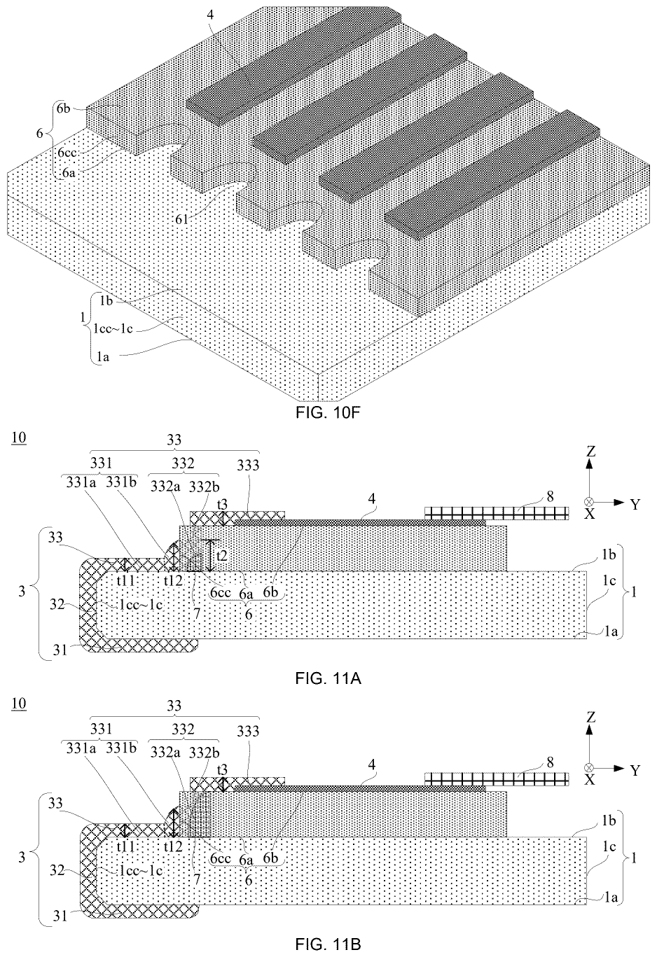

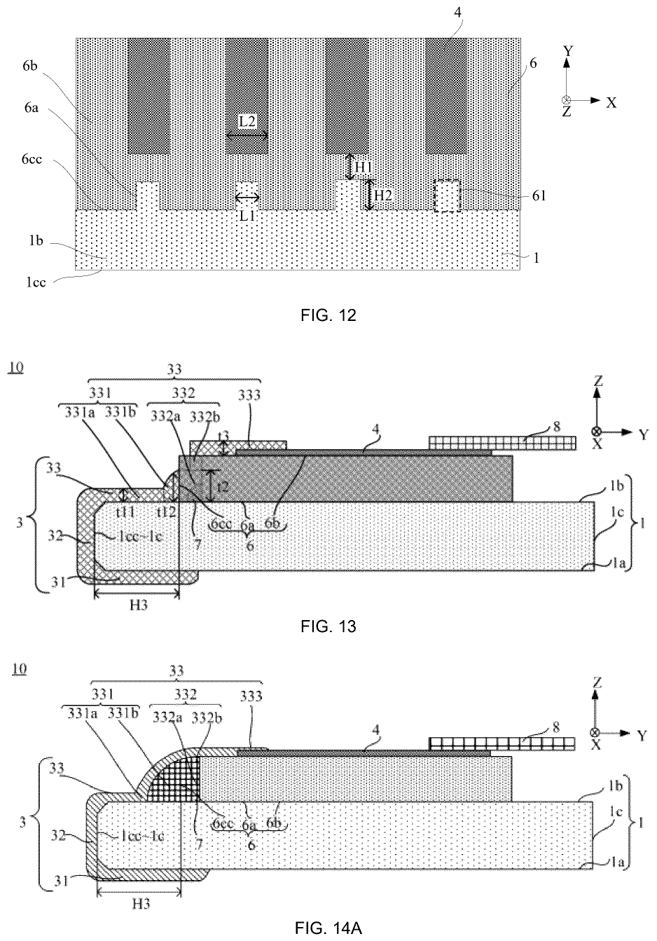

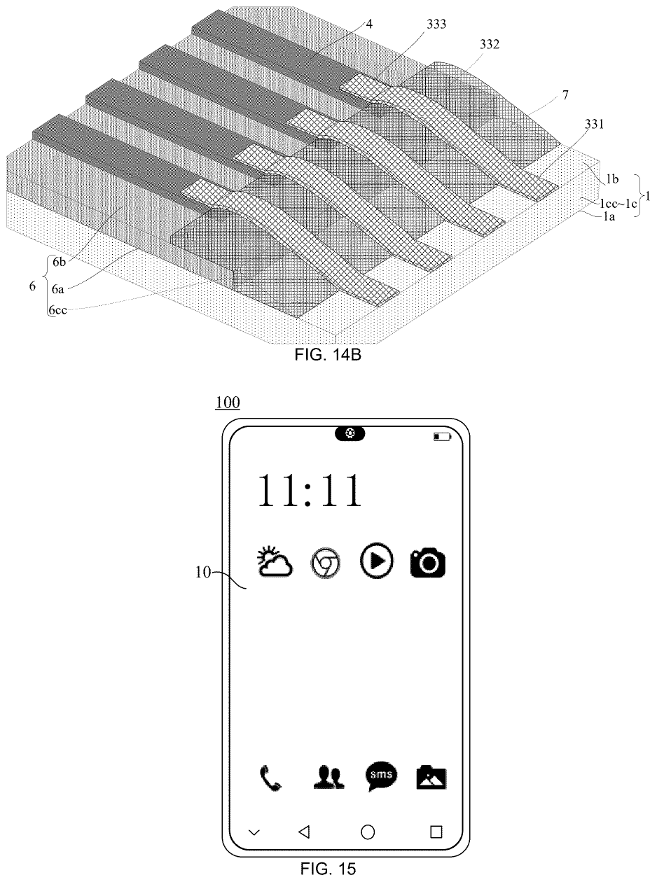

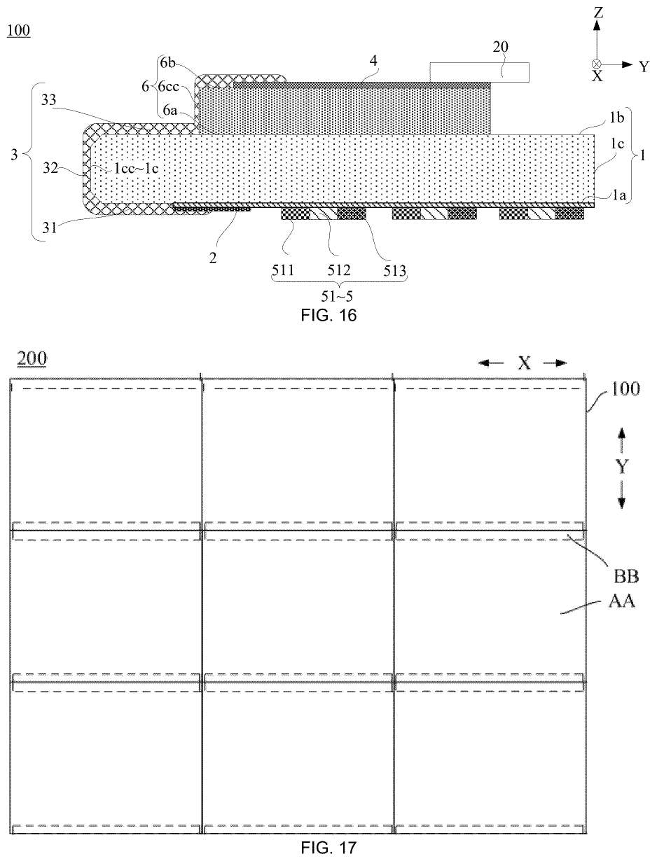

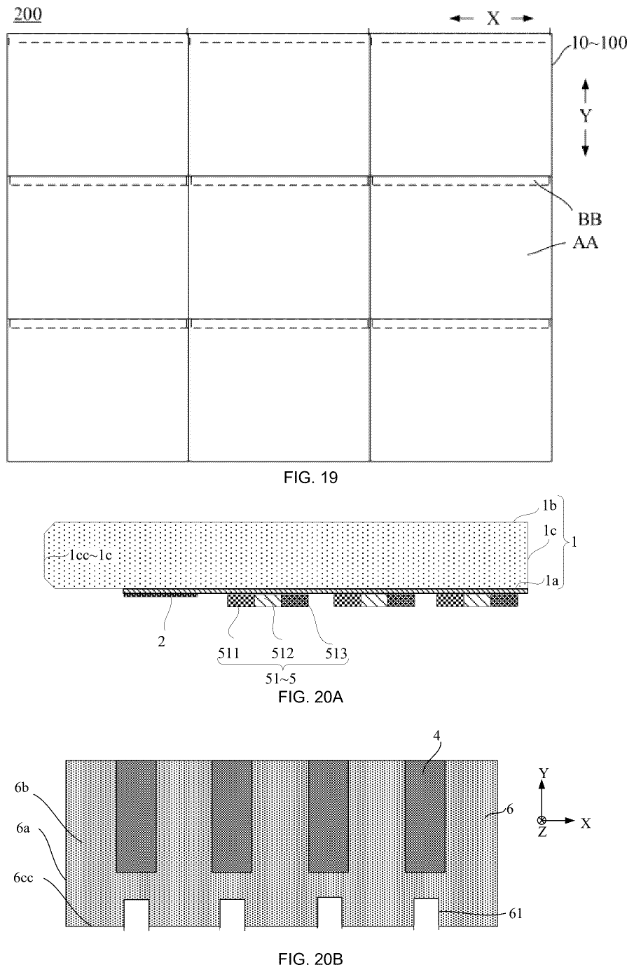

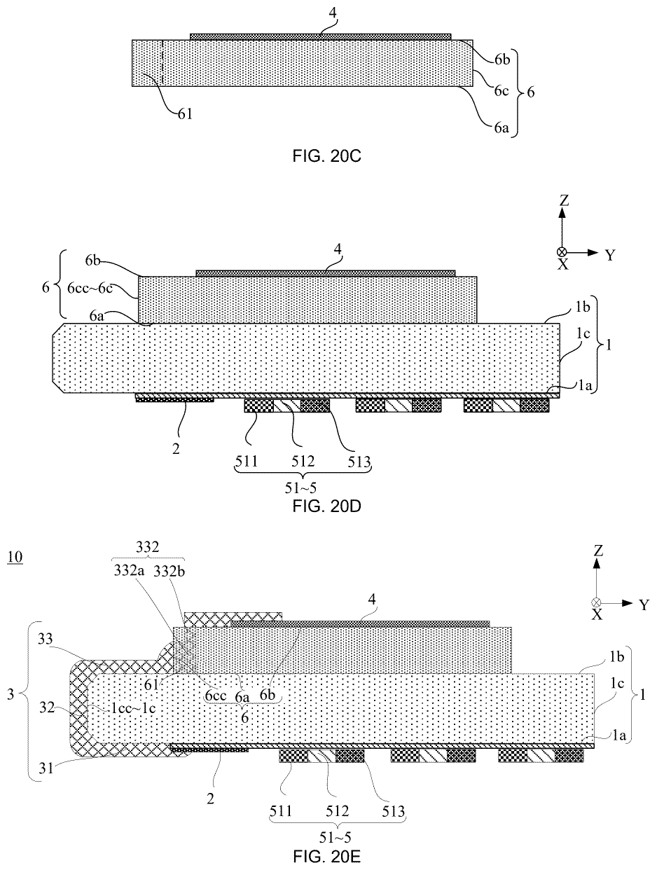

In the present disclosure, FIG. 1 is a cross-sectional view showing a structure of a display panel in accordance with some embodiments, FIG. 2 is a plan view showing a structure of a display panel in accordance with some embodiments, and FIG. 3 is another cross-sectional view showing a structure of a display panel in accordance with some embodiments. In order to facilitate a clear depiction of the structural changes in a display panel during a manufacturing process thereof, the following accompanying drawings are presented, in which FIG. 4 to FIG. 6 are top views showing a partial structure of a display panel; FIG. 7 to FIG. 9, FIG. 11A, FIG. 11B, FIG. 12, FIG. 13, FIG. 14A, and FIG. 14B are cross-sectional views showing a structure of a display panel in accordance with some embodiments; FIG. 10A to FIG. 10F, and FIG. 12 are top views showing structures of notches of a display panel in accordance with some embodiments; FIG. 15, FIG. 16 and FIG. 18 are plan views showing a structure of a display apparatus 100 in accordance with some embodiments; FIG. 17 and FIG. 19 are plan views showing a structure of a tiled display apparatus 200 in accordance with some embodiments; and FIG. 20A to FIG. 20E are structural diagrams corresponding to steps of manufacturing a display panel in accordance with some embodiments.

In some embodiments, as shown in FIG. 1, the display panel 10 includes a substrate 1, a plurality of front electrodes 2, a plurality of connecting traces 3, and a plurality of back electrodes 4. The substrate 1 includes a first surface 1a and a second surface 1b disposed opposite each other, and a plurality of first side surfaces 1c connecting the first surface 1a and the second surface 1b, with at least one first side surface 1c in the plurality of first side surfaces 1c of the substrate 1 being a first selected side surface 1cc. Each first selected side surface 1cc is provided with corresponding multiple connecting traces 3, and the multiple connecting traces 3 are arranged in parallel and at intervals. Each connecting trace 3 extends, via the first selected side surface 1cc, from the first surface 1a to the second surface 1b, that is, each connecting trace 3 includes a first trace 31 located on a side of the first surface 1a, a second trace 32 located on a side of the first selected side surface 1cc, and a third trace 33 located on a side of the second surface.

For example, as shown in FIG. 1 and FIG. 2, a side of the first surface 1a of the substrate 1 is a front side of the display panel 10, and the side of the first surface 1a of the substrate is provided with a display area AA and a bonding area BB. The display area AA is provided therein with film layer structures such as a driving circuit layer and a light-emitting device layer 5. The light-emitting device layer 5 includes light-emitting devices 51 of at least three colors, and those light-emitting devices of various colors include at least first color light-emitting devices 511, second color light-emitting devices 512 and third color light-emitting devices 513, where the first color, the second color and the third color are three primary colors (e.g., red, green and blue). For example, the light-emitting device 51 is a micro light-emitting diode (Micro LED) or a mini light-emitting diode (Mini LED).

As shown in FIG. 1 and FIG. 2, the side of the first surface 1a of the substrate 1 is the front side of the display panel 10, and the plurality of front electrodes 2 may be disposed in the bonding area BB and arranged in parallel and at intervals along a first direction X, where the first direction X is a direction parallel to a demarcation line between the first selected side surface 1cc and the first surface 1a. The plurality of front electrodes 2 are electrically connected to at least a portion of the driving circuit layer (not shown in the drawings). First traces 31 of the plurality of connecting traces 3 are disposed on the side of the first surface 1a of the substrate 1 and are electrically connected to the plurality of front electrodes 2 in one-to-one correspondence. An extension direction of the first traces 31 of the plurality of connecting traces 3 is, for example, a direction perpendicular to the first selected side surface 1cc of the substrate 1, that is, the extension direction is a second direction Y shown in FIG. 1.

For example, continuing to refer to FIG. 1, a side of the second surface 1b of the substrate 1 is a back side of the display panel 10, and third traces 33 of the plurality of connecting traces 3 are located on the side of the second surface 1b of the substrate 1, that is, a third trace 33 of a connecting trace 3 is a portion of the connecting trace 3 that is located on the back side of the display panel 10. An extension direction of the third traces 33 of the plurality of connecting traces 3 is, for example, the second direction Y. The plurality of back electrodes 4 are disposed on the side of the second surface 1b of the substrate and are arranged in parallel and at intervals along the first direction X. The plurality of back electrodes 4 may serve as bonding electrodes for connecting a flexible circuit board, and the third traces 33 of the plurality of connecting traces 3 are electrically connected to the plurality of back electrodes 4 in one-to-one correspondence.

A method for manufacturing the above-described display panel 10 includes: forming the driving circuit layer on the side of the first surface 1a of the substrate 1, the driving circuit layer including the plurality of front electrodes 2; and forming the plurality of back electrodes 4 on the side of the second surface 1b of the substrate 1. Here, a process for forming the driving circuit layer is, for example, an etching process; and a process for forming the plurality of back electrodes 4 is, for example, laser etching.

In this case, the etching is required on both the first surface 1a and the second surface 1b of the substrate 1, resulting in a high manufacturing cost of the display panel 10. Moreover, in a case where orthographic projections of the plurality of back electrodes 4 on the substrate 1 overlap with corresponding regions of the display area AA, laser light is possibly to pass through the substrate 1 and enter the display area AA on the first surface 1a, that is, partial energy of the laser light will pass through the substrate 1 to reach the display area AA, causing damage to film layers and devices in the display area AA, which leads to reliability problems such as local corrosion and failure of light-emitting devices to be lighted.

In some other examples, in a process of manufacturing the substrate 1, devices on the front side of the substrate are formed first, and then devices on the back side of the substrate are formed after a flipping process. During a process of flipping the substrate, it is easy to cause the substrate to come into contact with an equipment, which results in scratches and dirt as well as static electricity that cannot be discharged, affecting the yield and quality of a product.

In light of this, in order to reduce the manufacturing cost of the display panel 10 while avoiding the impact of the process on the back side of the substrate 1 on the film layers and devices on the front side, in some embodiments, as shown in FIG. 1 and FIG. 3, the display panel 10 further includes a bridging structure 6 disposed on the second surface 1b of the substrate 1. The bridging structure 6 includes a third surface 6a and a fourth surface 6b disposed opposite each other, and a plurality of second side surfaces 6c connecting the third surface 6a and the fourth surface 6b, where the third surface 6a is closer to the substrate 1 relative to the fourth surface 6b. At least one second side surface 6c in the plurality of second side surfaces 6c is a second selected side surface 6cc, and each second selected side surface 6cc corresponds to one first selected side surface 1cc.

As shown in FIG. 1, by arranging the bridging structure 6 on the second surface 1b of the substrate 1, the bridging structure 6 may serve as a carrier for the plurality of back electrodes 4. In a case where the display panel 10 includes the bridging structure 6, forming the plurality of back electrodes 4 may be accomplished in two steps as follows: first, the plurality of back electrodes 4 are formed on the fourth surface 6b of the bridging structure 6, and then the bridging structure 6 is connected to the second surface 1b of the substrate 1 with high precision, enabling the second surface 1b of the substrate 1 to be in contact with the third surface 6a of the bridging structure 6 while enabling the front electrodes 2 and the back electrodes 4 to face each other in a third direction Z. The above-described process of connecting the bridging structure 6 to the second surface 1b of the substrate 1 with high precision is, for example, adhesive bonding. By the above method, it is possible to reduce the cost while avoiding the impact of the etching process on the film layers and devices on the front side.

In some embodiments, as shown in FIG. 1, a back electrode 4 includes a first end 41 proximate to the first selected side surface 1cc and a second end 42 away from the first selected side surface 1cc. Here, the first end 41 is used to connect to a connecting trace 3, for example, the connecting trace laps over the first end 41; and the second end 42 is used to connect to a circuit board or a flexible circuit board, for example, the circuit board or the flexible circuit board laps over the second end 42.

For example, the display panel 10 may further include an insulating layer 9 located on a side of the back electrodes 4 away from the fourth surface of the bridging structure, and the insulating layer 9 exposes at least a first end 41 and a second end 42 of each back electrode 4.

The insulating layer covers the middle portion of each back electrode, for protecting the back electrode and preventing the back electrode from being corroded; and the insulating layer exposes the first end and the second end of the back electrode, enabling the back electrode to connect the connecting trace and the circuit board/flexible circuit board.

It will be noted that each second selected side surface 6cc corresponds to one first selected side surface 1cc, which means that the second selected side surface 6cc and the first selected side surface 1cc are the same in terms of number, and the second selected side surface 6cc is proximate to the first selected side surface 1cc corresponding thereto, the two being arranged along the third direction Z.

In some embodiments, as shown in FIG. 1 and FIG. 3, in a case where the display panel 10 includes the bridging structure 6, the third trace 33 of the connecting trace 3 extends from the second surface 1b of the substrate 1 to the fourth surface 6b of the bridging structure 6, that is, the third trace 33 is disposed on the second selected side surface 6cc and the fourth surface 6b of the bridging structure 6, and is electrically connected to the back electrode 4.

A process of manufacturing the above-described plurality of connecting traces 3 is as follows: the second traces 32, the first traces 31, and the third traces 33 are formed on the first selected side surface 1cc of the substrate 1, the first surface 1a of the substrate 1, and the second surface 1b of the substrate 1, respectively. For example, using a printing equipment, a conductive paste is formed by a printing process on regions corresponding to the connecting traces to be printed. For example, the conductive paste is formed on the first surface 1a, the first selected side surface 1cc and the second surface 1b of the substrate 1, the second selected side surface 6cc, and the fourth surface 6b in sequence, in which the printing process may be, for example, a three-dimensional printing process, and the conductive paste may be, for example, a silver paste. The three-dimensional printing process is a process in which a conductive paste inside a needle tube is extruded by using air pressure through a needle head with a certain aperture to a specific position on the substrate, and the conductive paste will form a trace after being cured. Since including multiple portions located on different surfaces, each connecting trace 3 needs to be formed by printing in batches, for example, the connecting trace 3 may be printed in three batches to form a portion located on the first surface 1a, a portion located on the first selected side surface 1cc, and a portion located on the second surface 1b, the second selected side surface 6cc and the fourth surface 6b. The printing process is, for example, as follows: the substrate is placed on a substrate table, which is movable along the second direction Y (moving left and right); the printing needle head P is placed along the third direction Z, and is kept in a fixed position in the second direction Y; the printing needle head moves in the third direction Z (moving up and down) with a constant paste spitting speed; by controlling a movement speed of the substrate table in the second direction Y and a movement speed of the printing needle head P in the third direction X, a distance between the printing needle head and a surface of the substrate is controlled to discharge the conductive paste on the surface of the substrate; and the conductive paste is cured to form a connecting trace with a relatively uniform width and a relatively uniform thickness, and the connecting trace has a good climbing profile at a segment gap of the bridging structure.

There are certain difficulties in the process of forming portions of the connecting trace located on the second surface 1b, the second selected side surface 6cc, and the fourth surface 6b by printing. Since the conductive paste has a certain fluidity, it is easy to cause the accumulation of the conductive paste in a case where the substrate table moves at a small speed, making the trace finally formed wider. As a result, a spacing between two adjacent traces in the first direction X will be too small after printing, which is prone to causing shorting, resulting in a short circuit. For example, as shown in FIG. 3, during the process of forming the portions of the connecting trace located on the second surface 1b, the second selected side surface 6cc, and the fourth surface 6b by printing, the printing needle head P is placed parallel to the third direction Z all the time. The printing needle head P and the substrate table have a relative movement path, which is indicated by the dashed arrows. The printing needle head P is located above a specific position of the second surface 1b of the substrate 1, which serves as a start printing position, to start printing. The printing needle head maintains a constant paste spitting speed to spit out the paste continuously, and the substrate table moves a specific distance to the left (F1 direction) along the second direction Y such that, after the printing needle head P relatively moves from the starting position to an end face of the bridging structure 6 proximate to the first selected side surface 1cc, the substrate table continues to move along the F1 direction. In this case, the printing needle head P moves upwardly (along the F2 direction) along the third direction Z slowly such that, the printing needle head P moves to a position directly above the fourth surface 6b of the bridging structure 6 and performs printing synchronously. That is to say, during the printing of the printing needle head P from the end face proximate to the first selected side surface 1cc to the position directly above the fourth surface 6b of the bridging structure 6, the relative movement path of the printing needle head P and the substrate table is as indicated by the dashed arrows. After that, the printing needle head P continues to hold the above position for printing, and then the substrate 1 continues to be moved to the left in the F1 direction by a specific distance relative to the printing needle head P until the printing ends and the printing needle head P is closed. Since the bridging structure has a certain thickness and there is a large segment gap between the second surface and the fourth surface, in order to ensure that the conductive paste does not have breakage after being cured, when printing is performed to a position of the segment gap, the movement speed of the substrate table along the second direction Y becomes slower, causing the printing needle head to stay for a longer period of time. As a result, a concentrated accumulation of the conductive paste will occur at this position, and after the conductive paste is cured, the risk of contact between two adjacent connecting traces 3 at this position greatly increases, that is, it is easy to cause a short-circuit between two adjacent connecting traces 3, which in turn affects the reliability of the display panel.

Moreover, referring to FIG. 3, in a case where the second selected side surface 6cc of the bridging structure 6 is perpendicular to the second surface 1b, during forming the plurality of connecting traces 3, since the fourth surface 6b of the bridging structure 6 is not at the same level as the second surface 1b of the substrate 1, the two form a step structure. Since a dimension of the second selected side surface 6cc in the third direction Z is greater than the thickness of the paste spit out by the printing needle head, it is difficult to discharge the conductive paste on the second surface 1b by the printing method, and there will be occur that the conductive paste accumulates at a bottom position of the segment gap but is thinner at a junction position of the second selected side surface 6cc and the fourth surface 6b, due to the effect of gravity and the leveling characteristics of the conductive paste. In addition, since the conductive paste will undergo deformation, such as volume contraction, during the curing process, the connecting trace 3 after being molded is prone to breakage at the junction position of the second selected side surface 6cc and the fourth surface 6b, which in turn leads to disconnection of the circuit of the display product, resulting in the failure of the display panel to perform display.

The thickness of the paste spit out by the printing needle head is a thickness of the conductive paste printed on the second selected side surface in the third direction. For example, a ratio of the thickness of the paste spit out by the printing needle head to a thickness of the bridging structure in the third direction ranges from 1:20 to 1:10. For example, the ratio of the thickness of the paste spit out by the printing needle head to the thickness of the bridging structure in the third direction is 1:20 or 1:10, and the thickness of the paste spit out by the printing needle head is 5 μm.

In light of this, referring to FIG. 4 to FIG. 6, a portion of the bridging structure 6 proximate to the first selected side surface 1cc is provided with a plurality of notches 61, and the plurality of notches 61 each have an opening facing the first selected side surface 1cc; and the plurality of back electrodes 4 are arranged in parallel and at intervals on the fourth surface 6b.

It can be understood that as shown in FIG. 4, the plurality of notches are disposed in the portion of the bridging structure 6 proximate to the first selected side surface 1cc, and the plurality of notches 61 each have an opening facing the first selected side surface 1cc, which means that from a side view angle of the display panel, the notch 61 is recessed from the second selected side surface 6cc toward the back electrode 4; and from a top view angle of the display panel, the notch 61 is recessed from the fourth surface 6b toward the third surface 6a.

For example, the thickness of the bridging structure 6 in the third direction Z ranges from 100 μm to 150 μm, with the third direction Z being the thickness direction of the substrate 1.

For example, a material of the bridging structure 6 may be, for example, glass, polyimide (PI, polyimide film), or the like.

In some examples, as shown in FIG. 4, the notch 61 is arranged to extend from the fourth surface 6b to the third surface 6a in the third direction Z, that is, a thickness of the notch 61 in the third direction Z is equal to the thickness of the bridging structure 6 in the third direction Z.

For example, the notch 61 passes through the entire bridging structure 6, with the bottom of the notch 61 exposing the second surface 1b of the substrate 1.

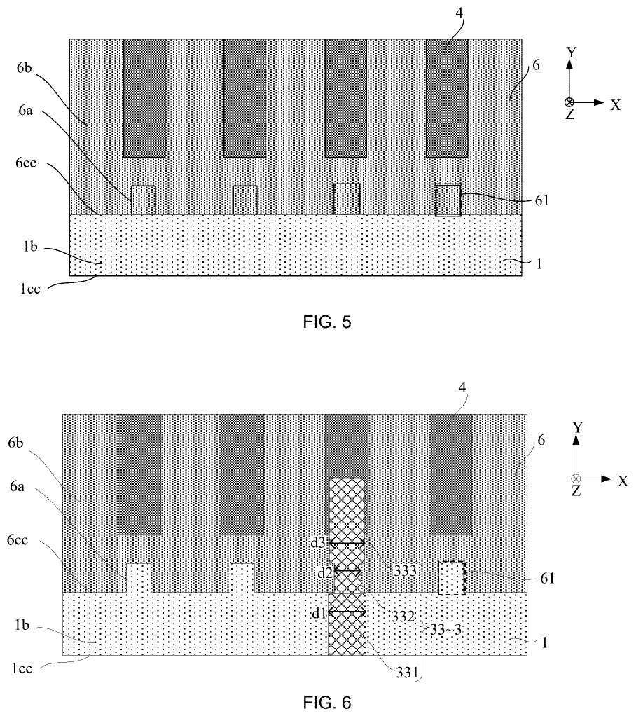

In some other examples, as shown in FIG. 5, the notch 61 is arranged to, from the fourth surface 6b, pass through a portion of the bridging structure 6 in the third direction Z, and in this time, a thickness of the notch 61 in the third direction Z is less than the thickness of the bridging structure 6 in the third direction Z.

For example, the notch 61 passes through a portion of the bridging structure 6, with the bottom of the notch 61 not exposing the second surface 1b of the substrate 1.

In some embodiments, each surface of the notch 61 is parallel to the third direction Z. That is, each surface of the notch 61 is perpendicular to the second surface 1b of the substrate 1.

In some other embodiments, a bottom surface of the notch 61 may have an included angle with the third direction Z, and the included angle ranges from 30° to 60°. The bottom surface of the notch is a surface proximate to the back electrode, and the bottom surface of the notch has the included angle with the third direction. The included angle ranges from 30° to 60°, that is, the bottom surface of the notch and the second surface 1b of the substrate form an obtuse angle therebetween, which ranges from 120° to 150° based on the previous description. The bottom surface of the notch is a slope, so that the paste reaches the fourth surface from the second surface through the bottom surface of the notch during the printing process in a relatively smooth manner, which reduces the printing difficulty, and further prevents the breakage of the connecting trace.

In some embodiments, as shown in FIG. 1 and FIG. 6, in a case where the display panel 10 includes the bridging structure 6, the third trace 33 of the connecting trace 3 includes a first portion 331, a second portion 332 and a third portion 333 that are connected in sequence, in which the second portion 332 is located in the notch 61, the third portion 333 is located on a side of the fourth surface 6b and connected to the back electrode 4, and the first portion 331 is located between the second portion 332 and the second trace 32.

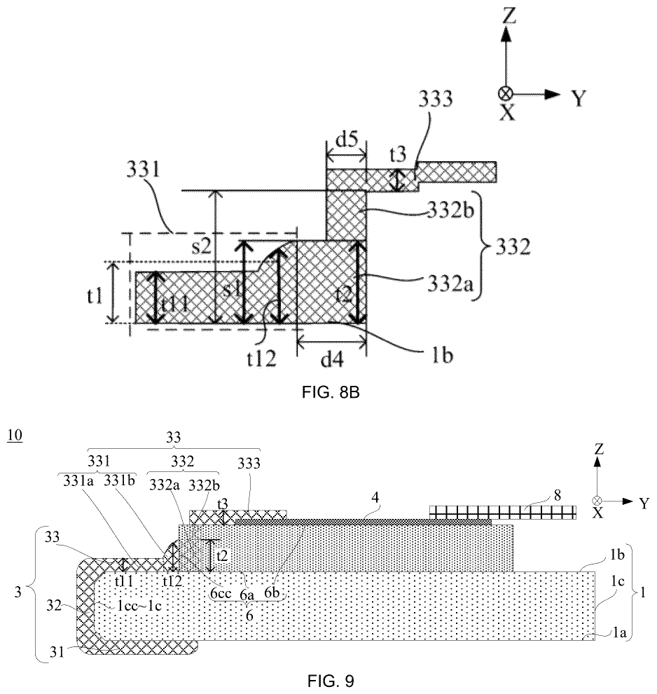

Referring to FIG. 7, the notch 61 is formed in a portion of the bridging structure 6 proximate to the first selected side surface 1cc, and the second portion 332 of the third trace 33 is located in the notch 61. That is to say, in the process of printing the second portion 332, the conductive paste is formed in the notch 61, and the notch 61 is capable of providing a certain limitation to the boundary of the conductive paste for forming the second portion 332, and preventing the conductive paste from spreading out along the first direction X to both sides. As the slowing down of the movement speed of the substrate table, the conductive paste is prone to produce accumulation in the notch. However, since the conductive paste is limited in the first direction X to a certain extent, the conductive paste accumulates only along the third direction Z. In other words, the thickness of the portion formed by the conductive paste gradually increases in the third direction Z. When the printing needle head P moves from the opening of the notch to the end thereof, the conductive paste (corresponding to a first sub-portion 332a as shown in FIG. 8B) has filled the bottom of the notch with a certain thickness, forming a primary step. When the printing needle head P moves slowly along the third direction Z and continues to print the conductive paste on a side wall of the notch proximate to the back electrode (corresponding to a second sub-portion 332b as shown in FIG. 8B), it is equivalent to continuing to print the conductive paste upwardly on the conductive paste that has already been accumulated at the bottom of the notch, and the segmental gap from the primary step to the fourth surface is reduced, which reduces the printing difficulty and enables the conductive paste to be distributed more uniformly. Compared to a case in which the notch 61 is not provided, the provision of the notch in the bridging structure enables the conductive paste to be formed at the segment gap in batches in the printing process of forming the second portion 332, which is equivalent to reducing the vertical height of a portion that needs to be formed in a single time. The large segment gap is divided into two small segment gaps in the third direction Z, the conductive paste is easier to be printed on the bridging structure, the thickness of the portion of the conductive paste formed at the junction position of the second selected side surface 6cc and the fourth surface 6b is increased, which in turn prevents the conductive paste from breaking during the curing process due to a too large segment gap. Moreover, since the second portion is limited inside the notch without overflowing, the short-circuit between second portions 332 of two adjacent connecting traces 3 may be avoided.

As shown in FIG. 5, in a case where the notch 61 passes through a portion of the bridging structure 6 along the third direction Z, that is, the bottom of the notch 61 does not expose the second surface 1b of the substrate 1, a first step is formed between the bottom of the notch 61 and the second surface of the substrate, and a second step is formed between the bottom of the notch 61 and the fourth surface 6b of the bridging structure 6. That is, the large segment gap between the second surface 1b and the fourth surface 6b is divided into two small segment gaps. During the printing process, the conductive paste is applied to the bottom of the notch 61 from the second surface 1b through the first step with a small segment gap, and after coating the bottom of the notch 61, the conductive paste continues to be applied to the fourth surface 6b through the second step. Since the notch 61 does not pass through the entire bridging structure, the segment gap between the bottom of the notch 61 and the fourth surface of the bridging structure 6 is reduced, and the accumulated conductive paste is raised when the conductive paste is formed in the notch, further reducing the segment gap between the surface of the conductive paste and the fourth surface 6b, thereby reducing the difficulty of printing the conductive paste on the side wall of the notch 61, enabling the formed connecting trace 3 to be less prone to breakage.

In some embodiments, referring to FIG. 6, a dimension d2 of the second portion 332 along the first direction X is less than a dimension of each of the first portion 331 and the third portion 333 along the first direction X.

It can be understood that referring to FIG. 6, the dimension of the first portion 331 in the first direction X is d1 and the dimension of the third portion 333 in the first direction X is d3. As can be seen with reference to the foregoing, the conductive paste is applied to the second surface 1b and the fourth surface 6b during the printing process. Since the conductive paste has a certain fluidity, the conductive paste will be leveled along the first direction X. As a result, the first portion 331 and the third portion 333 formed by the conductive paste after being cured have a larger dimension in the first direction X. Since the second portion 332 is located inside the notch 61, which is equivalent to limit the dimension d2 of the second portion 332 in the first direction X, the dimension d2 of the second portion 332 along the first direction X is lessened to a certain extent. That is, the dimension d2 of the second portion 332 along the first direction X is less than the dimensions of the first portion 331 and the third portion 333 along the first direction X, i.e., d2<d1/d3. In this way, even if there is an accumulation of the conductive paste at the notch 61, the dimension of the second portion 332 in the first direction X will not be too large owing to the limitation of the side wall of the notch, avoiding the short-circuit due to shorting of two adjacent third portions 333.

In some embodiments, as shown in FIG. 7, FIG. 8A and FIG. 8B, the second portion 332 includes a first sub-portion 332a and a second sub-portion 332b; an average distance s2 between the second sub-portion 332b and the second surface 1b is greater than an average distance s1 between the first sub-portion 332a and the second surface 1b; the second sub-portion 332b is connected to the third portion 333, and the first sub-portion 332a is connected to the first portion 331; and a dimension d4 of the first sub-portion 332a in the second direction Y is greater than a dimension d5 of the second sub-portion 332b in the second direction Y, the second direction Y being an extension direction of the third trace 33.

It will be noted that referring to FIG. 7, FIG. 8A and FIG. 8B, the average distance s1 between the second sub-portion 332b and the second surface 1b shown in the figures refers to an average value of distances between a side of the second sub-portion 332b away from the second surface 1b and the second surface 1b, and the average distance s1 between the first sub-portion 332a and the second surface 1b shown in the figures refers to an average value of distances between a side of the first sub-portion 332a away from the second surface 1b and the second surface 1b. The average distance s2 between the second sub-portion 332b and the second surface 1b is greater than the average distance s1 between the first sub-portion 332a and the second surface 1b, that is, the second sub-portion 332b is farther away from the second surface 1b relative to the first sub-portion 332a. The first sub-portion 332a is located at the bottom of the notch 61, and the second sub-portion 332b is located above the first sub-portion 332a and is in contact with the side wall of the notch 61.

For example, referring to FIG. 8A and FIG. 8B, the first sub-portion 332a has a dimension d4 in the second direction Y, the second sub-portion 332b has a dimension d5 in the second direction Y, and the dimension d4 of the first sub-portion 332a in the second direction Y is greater than the dimension d5 of the second sub-portion 332b in the second direction Y. According to FIG. 8A and FIG. 8B, it can be seen that in the cross-sectional views shown in FIG. 8A and FIG. 8B, the second portion 332, which is formed by the first sub-portion 332a and the second sub-portion 332b, has the shape of a step.

In some embodiments, as shown in FIG. 8A and FIG. 8B, the thickness t2 of the first sub-portion 332a is greater than or equal to the thickness t1 of the first portion 331, and the thickness t2 of the first sub-portion 332a is greater than the thickness t3 of the third portion 333.

It can be understood that referring to FIG. 8B and FIG. 9, the first portion 331 located on the second surface 1b in the figures includes two portions, a flat portion 331a and a sloped portion 331b, respectively. The flat portion 331a and the sloped portion 331b have unequal thicknesses, and the thickness t1 of the first portion 331 is an average value of thicknesses of portions of the first portion at respective positions. In the third trace 33, the flat portion 331a located on the second surface 1b and the third portion 333 located on the fourth surface 6b are both formed in conditions in which the conductive paste does not undergo climbing, whereas the second portion 332 in the third trace 33 is formed in conditions in which the conductive paste undergoes climbing. In the process of forming the first sub-portion 332a, the conductive paste accumulates more at a corresponding position due to the printing difficulty and the small movement speed of the substrate table. Therefore, the thickness t2 of the first sub-portion 332a formed at this position is greater than the thickness t1 of the first portion 331 and the thickness t3 of the third portion 333.

In addition, referring to FIG. 9, the sloped portion 331b, which is located on the second surface 1b, is connected to the first sub-portion 332a. The conductive paste is required to climb a slope during the printing of the sloped portion 331b, and likewise, the substrate table moves at a progressively smaller speed, resulting in an accumulation of the conductive paste, thus forming the sloped portion 331b shown in FIG. 9. The thickness t2 of the first sub-portion 332a is equal to the thickness of a portion of the sloped portion proximate to the position of the first sub-portion 332a, that is, the portion of the sloped portion of the first portion, which is in contact with the first sub-portion, forms a join transition.

In some embodiments, as shown in FIG. 9, a thickness t12 of a portion of the first portion 331 proximate to the bridging structure 6 is greater than a thickness t11 of a portion of the first portion 331 proximate to the first selected side surface 1cc.

For example, continuing to refer to FIG. 9, as can be seen from the foregoing, the first portion 331 includes the two portions, i.e., the flat portion 331a and the sloped portion 331b, in which a portion proximate to the bridging structure 6 is the sloped portion 331b, and a portion proximate to the first selected side surface 1cc is the flat portion 331a. As can be seen from the foregoing description of the printing process, the conductive paste accumulates more in the process of forming the sloped portion 331b, which corresponds to a climbing initial position, whereas there is no climbing in the process of forming the flat portion 331a, so the thickness t12 of the sloped portion 331b is greater than the thickness of the flat portion 331a. The thickness described above is an average value of thicknesses of the portions of the first portion 331 in corresponding regions on the second surface 1b, the thickness direction being the third direction Z.

In some embodiments, referring to FIG. 10A, FIG. 10C and FIG. 10E, a dimension L1 of the notch 61 in the first direction X is less than a dimension L2 of the back electrode 4 in the first direction X, the first direction X being perpendicular to an extension direction of the third trace 33.

It can be understood that according to the foregoing and in conjunction with FIG. 9, in the process of printing the third trace of the connecting trace 3, since the fourth surface 6b of the bridging structure 6 is not at the same level as the second surface 1b of the substrate 1, the two form a step structure. Since a dimension of the second selected side surface 6cc in the third direction Z is greater than the thickness of the paste spit out by the printing needle head, it is difficult to discharge the conductive paste on the second surface 1b by the printing method, and there will be occur that the conductive paste accumulates at a bottom position of the segment gap but is thinner at a junction position of the second selected side surface 6cc and the fourth surface 6b, due to the effect of gravity and the leveling characteristics of the conductive paste. In addition, since the conductive paste will undergo deformation, such as volume contraction, during the curing process, the connecting trace 3 after being molded is prone to breakage at the junction position of the second selected side surface 6cc and the fourth surface 6b. In order to avoid the breakage during manufacturing the third trace 33 of the connecting trace 3, and to reduce the climbing difficulty of the conductive paste in the printing process, the printing method is changed to a sectionalized climb printing. By setting the dimension L1 of the notch 61 in the first direction X to be less than the dimension L2 of the back electrode 4 in the first direction X, during the printing of the second portion 332, as the slowing down of the movement speed of the substrate table, the conductive paste will be limited by the notch 61 and can only accumulate along the third direction Z, which means that the thickness of the second portion 332 in the third direction Z is increased. In this way, it is possible to divide the segment gap between the bridging structure 6 and the second surface 1b into multiple small segment gaps to a certain extent, reducing the printing difficulty and thus avoiding the breakage of the molded connecting trace 3 at the junction position of the second selected side surface 6cc and the fourth surface 6b.

It will be noted that the above dimension L1 of the notch 61 in the first direction X is an average dimension of the notch 61 in the first direction X.

In some embodiments, with continued reference to FIG. 10A, FIG. 10C and FIG. 10E, a ratio of the dimension L1 of the notch 61 in the first direction X to the dimension L2 of the back electrode 4 in the first direction X ranges from 0.5 to 0.6.

It can be understood that in a case where a difference between the dimension L1 of the notch 61 in the first direction X and the dimension L2 of the back electrode 4 in the first direction X is too large, the dimension of the notch 61 is too small, resulting in the dimension of the second portion being too small, which may affect the transmission efficiency of an electrical signal on the connecting trace 3, and thus lead to a poor display of the display panel; and in a case where the difference between the dimension L1 of the notch 61 in the first direction X and the dimension L2 of the back electrode 4 in the first direction X is too small, the stacking effect will not be obvious during the actual printing of the connecting trace 3, thereby failing to fulfill the effect of reducing the segment gap. By setting the ratio of the dimension L1 of the notch 61 in the first direction X to the dimension L2 of the back electrode 4 in the first direction X in the above range, the difference between the dimension L1 of the notch 61 in the first direction X and the dimension L2 of the back electrode 4 in the first direction X may be maintained within a reasonable range, ensuring the transmission efficiency of the electrical signal on the display panel, and thereby improving the yield of the display panel. For example, the ratio of the dimension L1 of the notch 61 in the first direction X to the dimension L2 of the back electrode 4 in the first direction X is 0.5, 0.55 or 0.6.

In some embodiments, referring to FIG. 10A to FIG. 10F, the notch 61 has a plurality of cross-sections perpendicular to the second surface 1b and parallel to the first direction X. A dimension L11, in the first direction X, of a cross-section 61a farthest away from the first selected side surface 1cc in the plurality of cross-sections is less than or equal to a dimension L12, in the first direction X, of a cross-section 61b closest to the first selected side surface 1cc in the plurality of cross-sections.

For example, referring to FIG. 10A, the dimension L11, in the first direction X, of the cross-section farthest away from the first selected side surface 1cc in the plurality of cross-sections is equal to the dimension L12, in the first direction X, of the cross-section closest to the first selected side surface 1cc in the plurality of cross-sections, that is, an orthographic projection of the notch 61 on the second surface 1b is a rectangle. It can be understood that according to the foregoing and in conjunction with FIG. 9, in the process of printing the second portion 332 to be located in the notch 61, the movement speed of the substrate table is slowed down due to the difficulty in climbing the slope, which results in a higher degree of accumulation of the conductive paste at a position in the notch 61 farthest away from the first selected side surface 1cc than the conductive paste at a position in the notch 61 closest to the first selected side surface 1cc. That is, the thickness of a portion of the second portion 332 formed at the position in the notch 61 farthest away from the first selected side surface 1cc in the third direction Z is greater than the thickness of a portion of the second portion 332 formed at the position in the notch 61 closest to the first selected side surface 1cc in the third direction Z. In this case, an orthographic projection of the second portion 332 on a plane perpendicular to the second selected side surface 6cc is step-shaped, which is equivalent to alleviating the climbing difficulty in a single time. A height difference between the second surface 1b and the fourth surface 6b is divided into multiple small segment gaps to fulfill multiple climbs, avoiding the problem of breakage of the conductive paste due to the large height difference being too large during the curing process. Moreover, the dimension of the conductive paste in the first direction X will not become larger owing to the limiting effect of the position of the notch 61 in the first direction X, which may avoid short-circuit occurring in a localized region of two adjacent connecting traces 3.

For example, referring to FIG. 10C to FIG. 10F and the foregoing description, since the fourth surface 6b of the bridging structure 6 is not at the same level as the second surface 1b of the substrate 1, the two form a step structure. With the large segment gap from the second surface 1b to the fourth surface 6b, printing from the second surface 1b to the fourth surface 6b at one time will cause the conductive paste to climb upright on the second selected side surface 6cc with difficulty, increasing the printing difficulty. The dimension L11, in the first direction X, of the cross-section farthest away from the first selected side surface 1cc in the plurality of cross-sections is set to be less than the dimension L12, in the first direction X, of the cross-section closest to the first selected side surface 1cc in the plurality of cross-sections. For example, the dimension of the notch 61 becomes progressively smaller along a direction from the first selected side surface 1cc to the second selected side surface 6cc. In this way, during the movement of the substrate table for printing, it is possible to enable the conductive paste to accumulate at a position in the notch 61 away from the first selected side surface 1cc faster than at a position in the notch 61 proximate to the first selected side surface 1cc, that is, the height of the accumulated conductive paste is higher, at the same speed of the movement of the substrate table. In this way, not only the printing efficiency may be improved, but also it is easier to form and obtain the step-like second portion 332. That is, the thickness of the portion of the formed second portion 332 at the position in the notch 61 away from the first selected side surface 1cc in the third direction Z is greater than the thickness of the portion of the formed second portion 332 at the position in the notch 61 proximate to the first selected side surface 1cc in the third direction Z, which is equivalent to further alleviating the climbing difficulty in a single time. The height difference between the second surface 1b and the fourth surface 6b is divided into multiple small segment gaps to fulfill multiple climbs, avoiding the problem of breakage of the conductive paste due to the large height difference being too large during the curing process. Moreover, the dimension of the conductive paste in the first direction X will not become larger owing to the limiting effect of the position of the notch 61 in the first direction X, which may avoid short-circuit occurring in a localized region of two adjacent connecting traces 3.

In some embodiments, referring to FIG. 10A to FIG. 10F, an orthographic projection of the notch 61 on the second surface 1b has a shape of a rectangle, trapezoid, semi-circle, or semi-ellipse.

For example, referring to FIG. 10A, the orthographic projection of the notch 61 on the second surface 1b has the shape of a rectangle, which may ensure that the dimension L11, in the first direction X, of the cross-section farthest away from the first selected side surface 1cc in the plurality of cross-sections is equal to the dimension L12, in the first direction X, of the cross-section closest to the first selected side surface 1cc in the plurality of cross-sections, having the same beneficial effect as the above-described embodiments, which will not be repeated here.

For example, referring to FIG. 10C to FIG. 10F, the orthographic projection of the notch 61 on the second surface 1b has the shape of a trapezoid, semi-circle, or semi-ellipse, which may ensure that the dimension L11, in the first direction X, of the cross-section farthest away from the first selected side surface 1cc in the plurality of cross-sections is less than the dimension L12, in the first direction X, of the cross-section closest to the first selected side surface 1cc in the plurality of cross-sections, and the dimension of the notch 61 in the first direction X becomes progressively smaller along a direction from the first selected side surface 1cc to the second selected side surface 6cc. In this way, during the process of relative movement of the printing needle head P to print the conductive paste, the accumulation of the conductive paste in the notch 61 is gradually accelerated, and the height of the accumulated conductive paste gradually becomes higher, which is equivalent to forming a gentle slope, reducing the printing difficulty, thereby enabling the formed third portion to be more reliable, having has the same beneficial effect as the above embodiments, which will not be repeated here.

In some embodiments, referring to FIG. 11A and FIG. 11B, a side wall of the notch 61 proximate to the back electrode 4 is provided with a buffer structure 7, and the second portion 332 is located in the notch 61 and a portion of the second portion 332 is located on the buffer structure 7.

It will be noted that the thickness of a portion of the buffer structure 7 proximate to the side wall of the back electrode 4 in the third direction Z is less than or equal to the thickness of the notch 61 in the third direction Z, so as to ensure that the conductive paste can slowly climb while printing the second portion 332 of the connecting trace 3, thereby reducing the climbing difficulty.

For example, referring to FIG. 11A, the thickness of the portion of the buffer structure 7 proximate to the side wall of the back electrode 4 in the third direction Z is less than the thickness of the notch 61 in the third direction Z. The buffer structure 7 is located in the notch 61, and the buffer structure 7 is proximate to a side of the back electrode 4. The buffer structure 7 is provided, which is equivalent to constructing a gentle slope inside the notch 61 before printing the second portion 332 of the connecting trace 3, which decomposes the height difference between the second surface 1b and the fourth surface 6b to a certain extent. The second portion 332 in the notch 61 is able to climb slowly via the buffer structure 7, avoiding the problem of breakage of the conductive paste due to the too large difference in height during the curing process.

For example, referring to FIG. 11B, the thickness of the portion of the buffer structure 7 proximate to the side wall of the back electrode 4 in the third direction Z is equal to the thickness of the notch 61 in the third direction Z, that is, the thickness of the portion of the buffer structure 7 proximate to the side wall of the back electrode 4 in the third direction Z is equal to the thickness of the bridging structure 6 in the third direction Z. In the process of printing the second portion 332 of the connecting trace 3, the conductive paste can be evenly printed along a side of the buffer structure 7 away from the substrate 1. Moreover, in the process of continuing to print the third portion 333, since there is no height difference between the second portion 332 and the third portion 333, it is possible to enable the printing equipment to maintain a level transition printing at one height, while avoiding the breakage of the connecting trace 3 formed finally due to the height difference.

In some embodiments, a material of the buffer structure 7 includes an organic material.

For example, the material of the buffer structure 7 may be resin or polyimide.

In some embodiments, referring to FIG. 12, the notch 61 has a first spacing H1 in the second direction Y with the corresponding back electrode 4, and a ratio of a dimension H2 of the notch 61 in the second direction Y to the first spacing H1 ranges from 0.6 to 1.

For example, as shown in FIG. 12, the notch 61 is set to have the first spacing H1 in the second direction Y with the corresponding back electrode 4, which means that referring to FIG. 9, the fourth surface 6b of the bridging structure 6 forms a certain height difference with a side of the back electrode 4 away from the bridging structure 6, which is equivalent to a buffer step, with the main purpose of ensuring that during the printing of the second portion 332 of the connecting trace 3, the height difference is only equal to the thickness of the bridging structure 6 in the third direction Z. If there is no spacing between the notch 61 and the corresponding back electrode 4 in the second direction Y, that is, a side of the back electrode 4 proximate to the second selected side surface 6cc overlaps with a side of the notch 61 away from the second selected side surface 6cc, which results in the height difference becoming the sum of the thickness of the bridging structure 6 in the third direction Z and the thickness of the back electrode 4 in the third direction Z during the printing of the second portion 332 of the connecting trace 3. The greater height difference is unfavorable for printing of the connecting trace 3, and breakage is more likely to occur at the portion where the second portion 332 and the third portion 333 join in the connecting trace 3. Thus, the notch 61 is set to have the first spacing H1 in the second direction Y with the corresponding back electrode 4 to avoid the above problem.

It will be understood that setting the ratio of the dimension H2 of the notch 61 in the second direction Y to the first spacing H1 to be within the above range ensures that the leveling uniformity of the conductive paste is increased when the connecting trace 3 is formed by using the printing process, and that the connecting trace 3 is formed more reliably, thereby reducing the printing difficulty while enabling the conductive paste to be distributed uniformly. For example, the ratio of the dimension H2 of the notch 61 in the second direction Y to the first spacing H1 is 0.6, 0.8 or 1.

In some embodiments, referring to FIG. 13, a side of the bridging structure 6 proximate to the first selected side surface 1cc has a second spacing H3 in the second direction Y with the first selected side surface 1cc.

It can be understood that setting the side of the bridging structure 6 proximate to the first selected side surface 1cc to have the second spacing H3 in the second direction Y with the first selected side surface 1cc may give the following effect. In one aspect, it is possible to enable a step to be formed between the substrate 1 and the bridging structure 6, and compared to a design in which a boundary of the bridging structure 6 proximate to the first selected side surface 1cc overlaps or substantially overlaps with the first selected side surface 1cc, the above setting, while reserving a space for arranging the buffer structure 7, lengthens the length of a portion of the connecting trace 3 located between the bridging structure 6 and the first selected side surface 1cc. In this way, the conductive paste may climb slowly when the third trace 33 of the connecting trace 3 is formed by the printing process, thereby reducing the printing difficulty while enabling the conductive paste to be distributed further uniformly. In another aspect, it is possible to increase the connection firmness of the bridging structure 6 to the substrate 1, and prevent the positional accuracy of the back electrode 4 from being affected due to the movement of the bridging structure 6 in the subsequent processes of the display panel 10. Moreover, compared to a design in which a boundary of the bridging structure 6 proximate to the first selected side surface 1cc overlaps or substantially overlaps with the first selected side surface 1cc, the above setting may avoid undesirable phenomena such as warping of a boundary of the bridging structure 6 proximate to the first selected side surface 1cc.

The above embodiments are proposed with the provision of the notches 61 in the bridging structure 6, and the following describes some embodiments in which the bridging structure 6 is provided with no notch 61.

In some embodiments, referring to FIG. 14A and FIG. 14B, a buffer structure 7 is provided on a side of the bridging structure 6 proximate to the first selected side surface 1cc, and the connecting trace 3 is connected to the back electrode across the buffer structure 7, and the buffer structure 7 has a spacing from the first selected side surface 1cc.

It will be understood that by providing the buffer structure 7, in one aspect, the adherence tightness of a portion of the bridging structure 6 proximate to the first selected side surface 1cc and the substrate 1 is increased, and the problem of the back electrode 4 deviating from a set position due to the shifting of the bridging structure 6 is prevented, so as to ensure that the connecting trace 3 and the back electrode 4 may be efficiently connected together, and thus ensure that a driving signal can be transmitted to light-emitting devices through the connecting trace 3, ensuring that the display panel 10 may display images normally. In another aspect, since providing the buffer structure 7, the buffer structure forms a step, to decompose the height difference between the second surface 1b and the fourth surface 6b to a certain extent, so that the conductive paste may climb slowly through the buffer structure 7, reducing the printing difficulty, and it may be relatively easy to control a distance between the printing needle head P and the buffer structure, to improve the leveling uniformity of the conductive paste, thereby better controlling the width and thickness of the connecting trace and avoiding the problem of breakage of the conductive paste during curing due to a too large height difference.

In some examples, as shown in FIG. 14A, the thickness of a portion of the buffer structure 7 proximate to a side wall of the back electrode 4 in the third direction Z is equal to the thickness of the notch 61 in the third direction Z, that is, the thickness of the portion of the buffer structure 7 proximate to the side wall of the back electrode 4 in the third direction Z is equal to the thickness of the bridging structure 6 in the third direction Z. In the process of printing and forming the second portion 332 of the connecting trace 3, owing to the provision of the buffer structure 7, a side of the buffer structure 7 away from the second surface 1b is a curved surface with a certain slope. That is, the height difference between the fourth surface 6b of the bridging structure 6 and the second surface 1b of the substrate 1 becomes an overall gentle slope, and the conductive paste can evenly climb and be printed along the side of the buffer structure 7 away from the substrate 1. Moreover, in the process of continuing to print the third portion 333, since there is no height difference between the second portion 332 and the third portion 333, it is possible to enable the printing equipment to maintain a level transition printing at one height, while avoiding the breakage of the connecting trace 3 formed finally due to the height difference.

In some other examples, as shown in FIG. 14B, the buffer structure 7 is disposed on a side of the second selected side surface of the bridging structure, and the buffer structure 7 is further disposed on the fourth surface of the bridging structure. In this way, the buffer structure 7 covers a junction edge of the second selected side surface and the fourth surface of the bridging structure 6, so that the conductive paste may pass through a surface of the buffer structure to reach the fourth surface 6b and be connected to the back electrode 4, resulting in a smooth transition and reducing the risk of breakage due to the conductive paste being subjected to a large force at the junction edge of the second selected side surface and the fourth surface of the bridging structure. Further, the buffer structure 7 is disposed on the fourth surface of the bridging structure 6 and further laps over the plurality of back electrodes 4, and the surface of the buffer structure 7 has a gently sloped surface. In this way, the formed conductive paste may more easily lap over the back electrodes 4 along the gently sloped surface of the buffer structure 7 owing to the fluidity thereof, thereby further improving the manufacturing efficiency.

The embodiments of the present disclosure further provide a display apparatus 100. As shown in FIG. 15 and FIG. 1, the display apparatus 100 includes the display panel 10 as provided in any of the above embodiments and a driving circuit board 20. The driving circuit board 20 is electrically connected to the display panel 10. For example, the driving circuit board 20 is electrically connected to the back electrodes 4 of the display panel 10 via a flexible circuit board 8. Electrical signals provided by the driving circuit board 20 are transmitted to the driving circuit layer of the display panel 10 via the flexible circuit board 8, the back electrodes 4, the connecting traces 3, and the front electrodes 2, so as to control the light-emitting devices to emit light. The driving circuit board 20 is configured to transmit driving signals (i.e., the electrical signals) to the display panel 10 to drive the display panel 10 to display an image.

In some other embodiments, referring to FIG. 16, the driving circuit board 20 is directly connected to the back electrodes 4 of the display panel 10, and the electrical signals provided by the driving circuit board 20 are transmitted to the driving circuit layer of the display panel 10 via the back electrodes 4, the connecting traces 3, and the front electrodes 2 to control the light-emitting devices to emit light.

In the display apparatus 100, Mini LEDs or Micro LEDs serve as the light-emitting devices, which are small in size. For a substrate with a given area, the density in which the light-emitting devices 51 are arranged per unit area may be made to be higher, and it is also possible to implement independent driving or partitioned driving for the light-emitting devices 51, thereby improving the uniformity of the display brightness, and thus improving the display quality of the display apparatus 100.

The display apparatus 100 may be any apparatus capable of displaying images whether in motion (e.g., videos) or stationary (e.g., static images), and whether textual or graphical. More specifically, it is expected that the embodiments may be implemented in or associated with various electronic devices, which include (but are not limited to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, building structures, packaging and aesthetic structures (e.g., a display for an image of a piece of jewelry), and the like.

For example, the above display apparatus 100 may further include a frame, as well as other electronic accessories, in which the display panel 10 may be, for example, disposed within the frame.

The above display apparatus 100 has the same structure and beneficial technical effects as the display panel 10 provided in some of the above embodiments, which will not be repeated here.

The embodiments of the present disclosure further provide a tiled display apparatus 200.

In some embodiments, as shown in FIG. 17, the tiled display apparatus 200 includes a plurality of display apparatuses 100, as described in any of the above embodiments, tiled together.

In some embodiments, as shown in FIG. 19, the tiled display apparatus 200 includes a plurality of display panels 10, as described in any of the above embodiments, tiled together.

The following is stated as an example in which the tiled display apparatus 200 includes a plurality of display apparatuses 100 tiled together.

For example, as shown in FIG. 17 and FIG. 19, the display apparatus 100 has a planar shape of, for example, a rectangle.

In some examples, as shown in FIG. 19, the plurality of display panels 10 in the tiled display apparatus 200 are arranged in an array.

As shown in FIG. 1, in the display panel 10, a plurality of front electrodes 2 are arranged in parallel along a first direction X. Accordingly, a plurality of connecting traces 3 are also arranged in parallel along the first direction X. Another direction which is parallel to a first surface 1a of the display panel 10 and perpendicular to the first direction X is referred to as a second direction Y. The display apparatus 100 includes a plurality of side surfaces, and hereinafter, a side surface in the plurality of side surfaces of the display apparatus 100 that is proximate to the plurality of front electrodes 2 is described as a selected side surface of the display apparatus 100.

For example, as shown in FIG. 2, the display panel 10 includes a display area AA and two bonding areas BB located on opposite sides of the display area AA. The display panel 10 includes two groups of front electrodes 2, each group of front electrodes 2 includes multiple front electrodes 2, and the two groups of front electrodes 2 are disposed proximate to the two bonding areas BB, respectively.

Further, as shown in FIG. 17, in a case where the plurality of display apparatuses 100 each having a display panel 10 as shown in FIG. 2 are tiled together, selected side surfaces of two adjacent display apparatuses 100 are arranged, for example, along the first direction X. In this way, in multiple display apparatuses 100 arranged in a row along the first direction X, there is substantially no tiling seam between two adjacent display apparatuses 100 along the first direction X; and in multiple display apparatuses 100 arranged in a column along the second direction Y, there is a tiling seam between two adjacent display apparatuses 100. That is, a dimension of a tiling seam between two adjacent display apparatuses 100 in multiple display apparatuses 100 arranged in a row along the first direction X is less than a dimension of a tiling seam between two adjacent display apparatuses 100 in multiple display apparatuses 100 arranged in a column along the second direction Y.

In view of a small dimension of the bonding area BB in the second direction Y, when an image on the tiled display apparatus 200 is viewed actually by naked eyes, it is difficult for the naked eyes to distinguish the tiling seam between two adjacent display apparatuses 100 within the viewing distance, thereby enabling the tiled display apparatus 200 to present a relatively complete image, which may present a relatively good display effect.

For example, as shown in FIG. 18, the display panel 10 includes a display area AA and a bonding area BB located on one side of the display area AA. A plurality of front electrodes 2 are disposed in the bonding area BB.

Further, as shown in FIG. 19, in a case where the plurality of display apparatuses 100 each having a display panel 10 as shown in FIG. 18 are tiled together, selected side surfaces of two adjacent display apparatuses 100 are arranged, for example, along the first direction X. In this way, in multiple display apparatuses 100 arranged in a row along the first direction X, there is substantially no tiling seam between two adjacent display apparatuses 100 along the first direction X; and in multiple display apparatuses 100 arranged in a column along the second direction Y, there is a tiling seam between two adjacent display apparatuses 100. That is, a dimension of a tiling seam between two adjacent display apparatuses 100 in multiple display apparatuses 100 arranged in a row along the first direction X is less than a dimension of a tiling seam between two adjacent display apparatuses 100 in multiple display apparatuses 100 arranged in a column along the second direction Y.

In view of a small dimension of the bonding area BB in the second direction Y, when an image on the tiled display apparatus 200 is viewed actually by naked eyes, it is difficult for the naked eyes to distinguish the tiling seam between two adjacent display apparatuses 100 within the viewing distance, thereby enabling the tiled display apparatus 200 to present a relatively complete image, which may present a relatively good display effect.

The above tiled display apparatus 200 has the same structure and beneficial technical effects as the display apparatus 100 provided in some of the above embodiments, which will not be repeated here.

In another aspect, a method for manufacturing the display panel 10 is provided. As shown in FIG. 20A to FIG. 20E, the method for manufacturing the display panel 10 includes the following steps R1 to R6.

In R1, an initial substrate is provided.

In R2, a front film layer structure is formed on a front side of the initial substrate.

For example, the front film layer structure includes a driving circuit layer.

In R3, a plurality of front electrodes 2 arranged in parallel and at intervals are formed on the front side of the initial substrate.

In R4, the initial substrate is cut to form a plurality of substrates 1. As shown in FIG. 20A, the substrates 1 each include a first surface 1a and a second surface 1b disposed opposite each other, and a plurality of first side surfaces 1c connecting the first surface 1a and the second surface 1b; and the plurality of first side surfaces 1c include at least one first selected side surface 1cc.

The above film layer structures such as the front electrodes 2 and the driving circuit layer are all disposed on the front side of the substrate 1. The front electrodes 2 are proximate to the first selected side surface 1cc.

In R5, a bridging structure 6 is disposed on the second surface 1b of the substrate 1.

Referring to FIG. 20D, the bridging structure 6 includes a third surface 6a and a fourth surface 6b disposed opposite each other, and a plurality of second side surfaces 6c connecting the third surface 6a and the fourth surface 6b, where the third surface 6a is closer to the substrate 1 relative to the fourth surface 6b. The plurality of second side surfaces 6c include at least one second selected side surface 6cc, and each second selected side surface 6cc corresponds to one first selected side surface 1cc. A portion of the bridging structure 6 proximate to the first selected side surface 1cc is provided with a plurality of notches 61, and the plurality of notches 61 each have an opening facing the first selected side surface 1cc. For example, the plurality of notches 61 are formed in the bridging structure using an etching process.

The process described above of connecting the bridging structure 6 to the second surface 1b of the substrate 1 is, for example, an attachment with high precision.

Before R5, referring to FIG. 20B and FIG. 20C, a plurality of back electrodes 4 arranged at intervals are formed on the fourth surface 6b of the bridging structure 6. The plurality of back electrodes 4 are proximate to the second selected side surface 6cc, and each notch 61 in the plurality of notches 61 is arranged in correspondence with one back electrode 4. For example, the plurality of back electrodes 4 are formed using a wet etching process.

In R6, referring to FIG. 20E, a plurality of connecting traces 3 arranged in parallel and at intervals are formed. Each connecting trace 3 in the plurality of connecting traces 3 includes a first trace 31 located on a side of the first surface 1a, a second trace 32 located on a side of the first selected side surface 1cc, and a third trace 33 located on a side of the second surface 1b; the third trace 33 includes a first portion 331, a second portion 332 and a third portion 333 connected in sequence; and the second portion 332 is located in the notch 61, the third portion 333 is located on a side of the fourth surface 6b and connected to the back electrode 4, and the first portion 331 is located between the second portion 332 and the second trace 32.

For example, the process of forming the plurality of connecting traces 3 is a printing process. The printing process is, for example, three-dimensional printing.

In some embodiments, the method for manufacturing the display panel 10 further includes, before step R6, the following step R5-1.

In R5-1, referring to FIG. 11A and FIG. 11B, a buffer structure 7 is formed in the notch 61 of the bridging structure 6.

In some other embodiments, in a case where the bridging structure is provided with no notch 61, the method for manufacturing the display panel 10 further includes, before step R6, the following step R5-1.

In R5-1, referring to FIG. 14A and FIG. 14B, a buffer structure 7 is formed on a side surface of the bridging structure 6 proximate to the first selected side surface 1cc.

For example, a side of the buffer structure 7 provided in FIG. 14A proximate to the back electrode 4 is flush with the back electrode 4, with reference to the foregoing description for the specific effect.

For example, a side of the buffer structure 7 provided in FIG. 14B proximate to the back electrode 4 laps over the back electrode 4, which enables the printing equipment to perform uniform transition printing, while avoiding the phenomenon of breakage of the formed connecting trace caused by height difference.

The process of forming the above buffer structure 7 is, for example, three-dimensional printing.

The above manufacturing process, such as the printing process, is described only as exemplary, which is not intended to be a limitation of the actual manufacturing process.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, comprising:
a substrate, comprising a first surface and a second surface disposed opposite each other, and a plurality of first side surfaces connecting the first surface and the second surface, wherein at least one first side surface in the plurality of first side surfaces is a first selected side surface;
a bridging structure, disposed on the second surface and comprising a third surface and a fourth surface disposed opposite each other, the third surface being closer to the substrate relative to the fourth surface, wherein a portion of the bridging structure proximate to the first selected side surface is provided with a plurality of notches, and the plurality of notches each have an opening facing the first selected side surface;
a plurality of back electrodes, arranged in parallel and at intervals on the fourth surface, wherein each notch in the plurality of notches is arranged in correspondence with one back electrode; and
a plurality of connecting traces, arranged in parallel and at intervals, wherein each connecting trace comprises a first trace located on a side of the first surface, a second trace located on a side of the first selected side surface, and a third trace located on a side of the second surface; the third trace comprises a first portion, a second portion and a third portion connected in sequence; and the second portion is located in the notch, the third portion is located on a side of the fourth surface and connected to the back electrode, and the first portion is located between the second portion and the second trace.

2. The display panel according to claim 1, wherein a dimension of the second portion in a first direction is less than a dimension of each of the first portion and the third portion in the first direction, the first direction being perpendicular to an extension direction of the third trace.

3. The display panel according to claim 1, wherein the second portion comprises a first sub-portion and a second sub-portion, an average distance between the second sub-portion and the second surface is greater than an average distance between the first sub-portion and the second surface, the second sub-portion is connected to the third portion, and the first sub-portion is connected to the first portion, wherein
a dimension of the first sub-portion in a second direction is greater than a dimension of the second sub-portion in the second direction, the second direction being an extension direction of the third trace.

4. The display panel according to claim 3, wherein a thickness of the first sub-portion is greater than or equal to a thickness of the first portion, and the thickness of the first sub-portion is greater than a thickness of the third portion.

5. The display panel according to claim 1, wherein a thickness of a portion of the first portion proximate to the bridging structure is greater than a thickness of a portion of the first portion proximate to the first selected side surface.

6. The display panel according to claim 1, wherein a dimension of the notch in a first direction is less than a dimension of the back electrode in the first direction, the first direction being perpendicular to an extension direction of the third trace.

7. The display panel according to claim 6, wherein a ratio of the dimension of the notch in the first direction to the dimension of the back electrode in the first direction ranges from 0.5 to 0.6.

8. The display panel according to claim 1, wherein the notch has a plurality of cross-sections perpendicular to the second surface and parallel to a first direction; and a dimension, in the first direction, of a cross-section farthest away from the first selected side surface in the plurality of cross-sections is less than or equal to a dimension, in the first direction, of a cross-section closest to the first selected side surface in the plurality of cross-sections, the first direction being perpendicular to an extension direction of the third trace.

9. The display panel according to claim 8, wherein an orthographic projection of the notch on the second surface has a shape of a rectangle, trapezoid, semi-circle or semi-ellipse.

10. The display panel according to claim 1, further comprising a buffer structure, disposed on a side wall of the notch proximate to the back electrode, wherein the second portion is located in the notch and a portion of the second portion is located on the buffer structure.

11. The display panel according to claim 1, wherein the notch has a first spacing in a second direction with the back electrode, the second direction being an extension direction of the third trace; and
a ratio of a dimension of the notch in the second direction to the first spacing ranges from 0.6 to 1.

12. The display panel according to claim 1, wherein a side of the bridging structure proximate to the first selected side surface has a second spacing in a second direction with the first selected side surface, the second direction being an extension direction of the third trace.

13. A display apparatus, comprising the display panel according to claim 1; and
a driving circuit board, electrically connected to the display panel and configured to drive the display panel to display an image.

14. A tiled display apparatus, comprising a plurality of display apparatuses, each according to claim 13, tiled together.

15. The display panel according to claim 1, wherein the notch extends from the fourth surface to the third surface.

16. The display panel according to claim 1, wherein the notch passes through, from the fourth surface, a portion of the bridging structure.

17. The display panel according to claim 1, wherein the notch has a bottom surface inclined toward the back electrode, at an obtuse angle formed with the second surface.

18. The display panel according to claim 17, wherein the obtuse angle ranges from 120° to 150°.

19. The display panel according to claim 10, wherein a dimension, in a thickness direction of the substrate, of a portion of the buffer structure proximate to the back electrode is less than or equal to a dimension, in the thickness direction of the substrate, of the notch.

20. A tiled display apparatus, comprising a plurality of display panels, each according to claim 1, tiled together.
